(19) United States
(12) Patent Application Publication
(10) Pub. No.: US 2005/0158468 A1
(43) Pub. Date: Jul. 21, 2005

(54) Method for manufacturing carbon composites

(76) Inventors: John Gaffney, North Chelmsford, MA (US); David Giannelli, Burlington, MA (US); Roger Masse, Dracut, MA (US); Raymond Loszewski, Windham, NH (US); Robert Froberg, Lower Macungie, PA (US)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 10/760,714

(22) Filed: Jan. 20, 2004

(51) Int. Cl. C23C 16/00

(52) U.S. Cl. 427/249.1

(57) ABSTRACT

Carbon-composite materials can be useful for a wide range of applications such as in friction applications as found in automotive continuous slip service in torque converter clutches. Carbon-composites may also be used as fluid diffusion layers in electrochemical fuel cells. Continuous processing of such carbon composites, though long found to be difficult due to unacceptably long dwell times can be done with the use of propane as the hydrocarbon gas, particularly when done at temperatures between 1200 and 2000° C. and 0.1 and 1 mm Hg. In particular, such methods lead to carbon composites with suitable frictional properties.

### BACKGROUND OF THE INVENTION

1. Field of the Invention

The invention relates to carbon composite materials. More particularly, the invention relates to a method for manufacturing carbon fiber composite materials as used, for example, in friction applications such as automotive continuous slip service such as that in torque converter clutches or as fluid diffusion layers in electrochemical fuel cells.

2. Description of the Related Art

Carbon-carbon composite clutch friction materials, as disclosed in U.S. Pat. Nos. 4,700,823 and 6,132,877, are typically used in automotive continuous slip service such as that found in torque converter clutches. As a liquid lubricant is used, such as an oil or other suitable cooling medium, this is called a wet friction application. In such wet friction applications, at least two cooperating members are adapted to be moved into and out of frictional engagement with mutually opposing surfaces. At least one of the cooperating members comprises a friction material. The liquid lubricant circulates about and between the friction material and the opposing surface.

Woven fabrics of carbonized or graphitized polyacrylonitrile (PAN) or rayon fibers have been used as a substrate for infiltration with additional carbon. The woven carbon fabric with a carefully controlled amount of carbon infiltration produces a composite product having suitable porosity and flexibility for clutch operations with a liquid lubricant. Typically, the infiltration process involves coating pyrolytic carbon by a chemical vapor deposition (CVD) process on the fibers of a cloth substrate.

The CVD process densities the cloth substrate thereby imparting strength to the material. During the CVD process, the fabric may be placed in a furnace and the furnace is evacuated of air and heated to 1000° C. A carbonaceous gas, typically methane, is flowed around the fabric. The gas decomposes to deposit carbon (pyrolytic carbon) in the fabric. CVD is continued or repeated until a composite of a desired density and porosity is obtained. The friction surface of the composite may then be machined with a surface grinder to remove high spots from the infiltrated fabric.

In particular, FIGS. 3 and 4 of the '877 patent illustrate a single woven fabric substrate layer formed of fibers of twisted carbon filaments woven in an eight harness satin weave. The eight harness weave is a loose mesh-like weave with a thickness of between 0.38 and 0.77 mm. Pyrolytic carbon particles are deposited by CVD on the fibers to fill in spaces between filaments as well as gaps between the fibers.

A common problem with known CVD techniques is that the dwell time may take from several tens to hundreds of hours, which is unsuitable for large-scale continuous processing. The process time may be reduced by increasing the temperature though this may result in increased formation of soot or undesirable forms of carbon crystal structures, which may impair the ability of the material to function as a suitable friction material. Soot results from homogeneous nucleation in the gas phase such that carbon particles bind to each other instead of depositing in the fabric. Increasing the temperature in the CVD process conditions may also produce more graphitic material, which may be softer and have reduced structural integrity. This problem is recognized in U.S. Pat. No. 5,348,774 where the dwell time is reduced by creating a thermal gradient across the substrate. While the method described in the '774 patent reports a reduction of the dwell time from 600-1200 hours to 26-30 hours, this is still not amenable to continuous processing which requires a dwell time of less than 10 hours and preferably even less than 5 hours.

U.S. Pat. Nos. 3,944,686 and 4,048,953 disclose a continuous CVD process to infiltrate a porous fibrous carbon with pyrolytic carbon. In the '686 and '953 patents, the carbon composite is used as a fluid diffusion layer in an electrochemical fuel cell. Fuel cells convert fuel and oxidant reactants to generate electric power and reaction products. They generally employ an electrolyte disposed between cathode and anode electrodes. A catalyst typically induces the desired electrochemical reactions at the electrodes. Preferred fuel cell types include polymer electrolyte membrane (PEM) fuel cells that comprise an ion-exchange membrane as electrolyte and operate at relatively low temperatures.

PEM fuel cells employ a membrane electrode assembly (MEA) that comprises the ion-exchange membrane disposed between the cathode and anode. Each electrode contains a catalyst layer, comprising an appropriate catalyst, located next to the solid polymer electrolyte. The catalyst is typically a precious metal composition (e.g., platinum metal black or an alloy thereof) and may be provided on a suitable support (e.g., fine platinum particles supported on a carbon black support). The electrodes may also contain a porous, electrically conductive substrate that may be employed for purposes of mechanical support, electrical conduction, and/or reactant distribution, thus serving as a fluid diffusion layer. Flow fields for directing the reactants across one surface of each electrode or electrode substrate, are disposed on each side of the MEA. In operation, the output voltage of an individual fuel cell under load is generally below one volt. Therefore, in order to provide greater output voltage, numerous cells are usually stacked together and are connected in series to create a higher voltage fuel cell stack.

The fluid diffusion layer may be a carbon composite as in the '686 and '953 patents or more typically a woven or non-woven carbon fabric or paper. Carbon fabrics are, however, highly compressible by nature and present non-uniform surfaces at the catalyst/membrane interface. Resin or resin/powder matrix filled carbon paper substrates rely on their carbonized matrix fill for their fluid diffusion layer attributes but require multiple processing steps to achieve balanced permeability and conductivity suitable for use in a fuel cell. Uniformity and reproducibility of such multiple processing also poses significant problems. Many of these problems may be avoided by using carbon composite materials as disclosed in the '686 and '953 patents. However, formation of soot remains a significant problem in using CVD despite claims in the '686 and '953 patents that sooting may be prevented in their continuous manufacture.

Accordingly, there remains a need in the art for chemical vapor deposition conditions under which formation of soot is eliminated or significantly reduced, yet which remain amenable to continuous processing. The present invention fulfills this need and provides further related advantages.

### BRIEF SUMMARY OF THE INVENTION

In brief, the present invention provides a method for the manufacture of a carbon composite material by chemical vapor deposition under conditions that allow for continuous processing with minimal formation of soot. Such carbon composite materials may be used as friction substrates, for example, in a torque converter clutch or as fluid diffusion layers in electrochemical fuel cells.

In one embodiment of the present invention, a method is provided for manufacturing a carbon composite material by:
a) providing a carbon substrate; and
b) depositing pyrolitic carbon on the carbon substrate by decomposing a propane gas at an elevated temperature sufficient to pyrolize the propane gas at a subatmospheric pressure less than 100 mm Hg.

The carbon composite may then be incorporated into a torque converter clutch for use in an engine for an automobile. Alternatively, the carbon composite may be incorporated into a membrane electrode assembly for use in an electrochemical fuel cell.

In another embodiment, the carbon composite is a friction material and the method of manufacture comprises:
a) providing a carbon substrate; and
b) depositing pyrolitic carbon on the carbon substrate by decomposing a propane gas at an elevated temperature sufficient to pyrolize the propane gas at a subatmospheric pressure to produce the friction material with a friction test having an average slope greater than −0.09 Newton Meters/RPM between 20 and 60 revolutions per minute at 400 kilo-Pascals.

The carbon substrate may be, for example, a felt or a woven fabric composed of carbon or graphite.

To avoid the formation of soot, the elevated temperature may be, for example, below 2000° C., more particularly below 1800° C. and even more particularly below 1600° C. Conversely, to allow for continuous processing with sufficiently low residence times for the CVD, the temperature may be, for example, above 1200° C., more particularly above 1300° C., and even more particularly above 1500° C. In an embodiment, the elevated temperature is about 1600° C.

The propane gas may be substantially pure or diluted with an inert carrier gas such as, for example, nitrogen or argon. If diluted, temperature and pressure may be optimized accordingly.

The subatmospheric pressure may be, for example, less than 50 mm Hg, more particularly, less than 10 mm Hg and even more particularly, less than 5 mm Hg, less than 3 mm Hg, and even less than 1 mm Hg. Further, the subatmospheric pressure may be greater than 0.1 mm Hg. In an embodiment, the subatmospheric pressure is from 0.1 to 1 mm Hg.

The depositing steps may be for example, less than 10 hours, more particularly, less than 5 hours, even more particularly less than 3 hours, even more particularly less than 2 hours. In an embodiment, the depositing step is for about one hour. In another embodiment, the method is continuous.

In the context of this application, the word “about” means plus or minus half of the significant figure. For greater certainty, the significant figure for 1600° C. is the hundreds of a degree.

These and other aspects of the invention will be evident upon reference to the attached figures and following detailed description.

### BRIEF DESCRIPTION OF THE DRAWINGS

FIG. 1 is an SEM cross-sectional view of a carbon substrate densified with pyrolitic carbon.

FIG. 2 is representative graph of average corrected/reduced torque against average slip speed used to test the frictional properties of a densifed carbon substrate.

### DETAILED DESCRIPTION OF THE INVENTION

Chemical vapor deposition typically uses methane as the hydrocarbon source for the pyrolitic carbon. Efforts to render the process more amenable to continuous processing by increasing the operating temperatures to speed up the process are typically counter-productive as the formation of soot then becomes problematic.

After extensive testing as shown in more detail below, propane can be used as the hydrocarbon source for the pyrolitic carbon in such a manner that carbon substrates are densified relatively quickly and with minimal formation of soot.

Table 1 shows eight trials where a carbon fabric, supplied by BMP, was densified with 100% propane at 0.5 mm Hg pressure. The propane was 99.1% purity (AirGas). Once the temperature reached the relevant process temperature, propane was introduced for the indicated residence time. At the conclusion of the residence time, the densified substrates were cooled and measured for average sheet thickness and density. These results are summarized in Table 1.

TABLE 1

| | Process | Residence | Average Sheet | Density/ |
|---|---|---|---|---|
| Trial | Temp/° C. | Time/hour | Thickness/mils | g/cc |
| 1 | 1500 | 3 | 31.59 | 1.63 |
| 2 | 1600 | 3 | 29.95 | 1.70 |
| 3 | 1600 | 1 | 31.16 | 1.26 |
| 4 | 1600 | 0.5 | 31.60 | 1.02 |
| 5 | 1700 | 3 | 31.34 | 1.70 |
| 6 | 1700 | 1 | 30.46 | 1.42 |
| 7 | 1700 | 0.5 | 31.73 | 1.10 |
| 8 | 1800 | 2.5 | 31.27 | 1.62 |

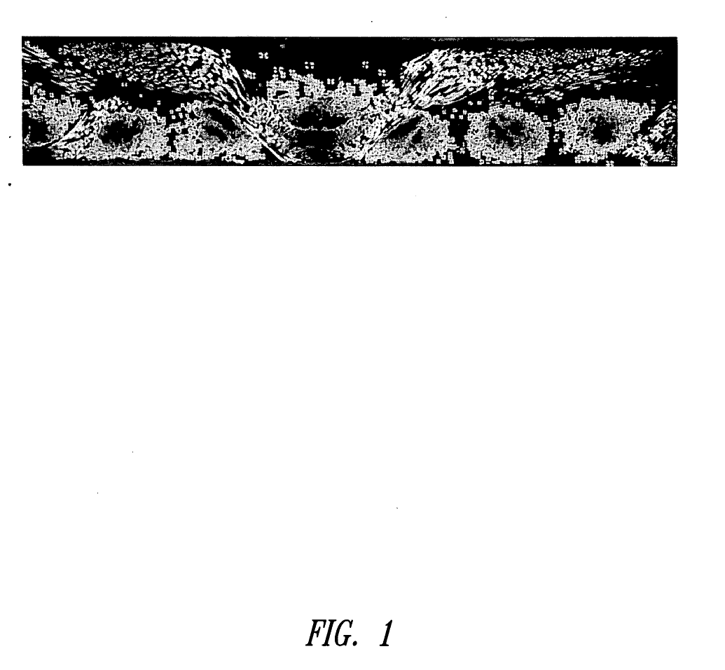

Propane can thus be used as a suitable hydrocarbon source for the continuous CVD of carbon substrates unlike other hydrocarbon gases such as methane (as discussed above). At 1200° C. (not shown), the residence time is too long to be suitable for continuous processing though this is not a concern at higher temperatures. An SEM cross-sectional view of a carbon substrate subjected to a CVD at 1600° C. for one hour on an 8 harness satin fabric is shown in FIG. 1.

Generally, the trials shown in Table 1 illustrate the suitability of propane for chemical vapor deposition and in particular for the use of propane in continuous processing. This may be adequate for some applications, such as, for example, when used as a fluid diffusion layer in an electrochemical fuel cell. However, additional testing is required to know if any particular material is also suitable for use as a friction material.

U.S. Pat. No. 6,132,877 discloses that a high density is desired in friction materials. High density is defined therein as being in the range of 1.3 g/cc to about 1.5 g/cc. As shown below, simply measuring density is not sufficient to ascertain whether a material is suitable as a friction material. In fact, trial 4 with a density of only 1.02 g/cc is shown to be an exemplary friction material. While density alone does not correlate well with frictional properties, it is still unknown what properties relate well to suitability as a friction material. It is thus necessary to test a material to see if it can be used as a friction material.

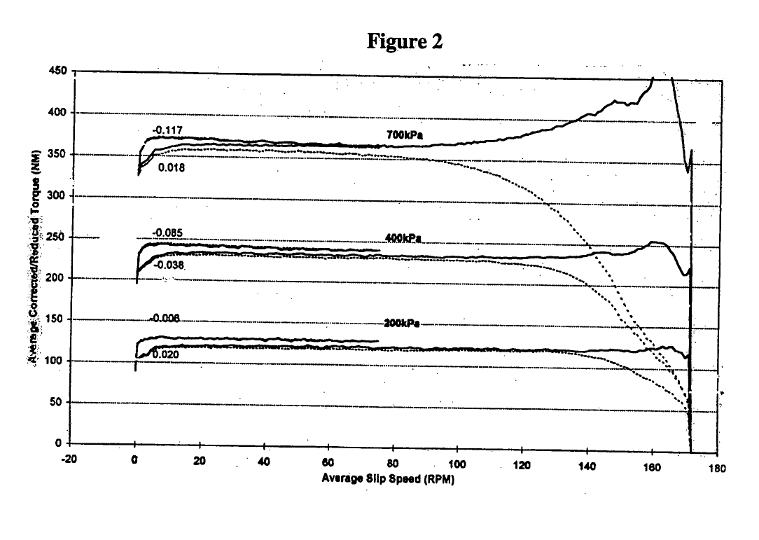

An appropriate test is to plot the average corrected, reduced torque against the average slip speed at various pressures. FIG. 2 shows typical results from such a test at 200 kPa, 400 kPa and 700 kPa. To determine the suitability of the densified substrate as a friction material, the average slope at 400 kPa between 20 RPM and 60 RPM should be ascertained. This can be calculated by performing a linear regression on the data between 20 and 60 RPM. If this average slope is greater than −0.09 NM/RPM, then the substrate may be considered to be suitable for use as a friction material.

Table 2 shows the average slope from friction test for each trial from Table 1. The test was repeated for each material and the results from each test are shown in Table 2. Trials 1, 3, 4 and 6 are clearly suitable for use as a friction material whereas trials 5, 7 and 8 are clearly unsuitable for such use. Trial 2 may be suitable though additional testing may be indicated.

TABLE 2

Friction Test/NM/RPM

| Trial | Test 1 | Test 2 |
|---|---|---|
| 1 | +0.001 | −0.019 |
| 2 | −0.040 | +0.097 |
| 3 | −0.018 | −0.014 |
| 4 | +0.029 | −0.076 |
| 5 | −0.135 | −0.147 |
| 6 | −0.047 | −0.092 |
| 7 | −0.137 | −0.138 |
| 8 | −0.120 | −0.118 |

As mentioned above, density does not appear to be a good indicator of suitability of these carbon substrates as friction materials. Temperature appears to be a better indicator where higher processing temperatures tend to result in poorer friction materials, particularly temperatures above 2000° C., more particularly above 1800° C. and more particularly above 1700° C. However, the methods that led to materials 1, 3, 4 and 6 are all suitable for the preparation of a friction material. Further, these methods are amenable to continuous processing due to sufficiently low dwell times.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing, it will be appreciated that, although specific embodiments of the invention have been described herein for purposes of illustration, various modifications may be made without deviating from the spirit and scope of the invention. Accordingly, the invention is not limited except as by the appended claims.

1. A method for manufacturing a carbon composite material comprising:
providing a carbon substrate; and
depositing pyrolitic carbon on the carbon substrate by decomposing a propane gas at an elevated temperature sufficient to pyrolize the propane gas at a subatmospheric pressure less than 100 mm Hg.

2. The method of claim 1 wherein the elevated temperature is below 2000° C.

3. The method of claim 1 wherein the elevated temperature is below 1800° C.

4. The method of claim 1 wherein the elevated temperature is below 1700° C.

5. The method of claim 1 wherein the elevated temperature is above 1200° C.

6. The method of claim 1 wherein the elevated temperature is above 1300° C.

7. The method of claim 1 wherein the elevated temperature is above 1500° C.

8. The method of claim 1 wherein the elevated temperature is about 1600° C.

9. The method of claim 1 wherein the propane gas is substantially pure propane.

10. The method of claim 1 wherein the propane gas is diluted with an inert carrier gas.

11. The method of claim 1 wherein the subatmospheric pressure is less than 50 mm Hg.

12. The method of claim 1 wherein the subatmospheric pressure is less than 10 mm Hg.

13. The method of claim 1 wherein the subatmospheric pressure is less than 5 mm Hg.

14. The method of claim 1 wherein the subatmospheric pressure is less than 3 mm Hg.

15. The method of claim 1 wherein the subatmospheric pressure is less than 1 mm Hg.

16. The method of claim 1 wherein the subatmospheric pressure is greater than 0.1 mm Hg.

17. The method of claim 1 wherein the subatmospheric pressure is from 0.1 to 1 mm Hg.

18. The method of claim 1 wherein the carbon substrate is a carbon fabric.

19. The method of claim 18 wherein the carbon fabric is woven.

20. The method of claim 1 wherein the depositing step is for less than 10 hours.

21. The method of claim 1 wherein the depositing step is for less than 5 hours.

22. The method of claim 1 wherein the depositing step is for less than 3 hours.

23. The method of claim 1 wherein the depositing step is for less than 2 hours.

24. The method of claim 1 wherein the depositing step is for about 1 hour.

25. The method of claim 1 wherein the method is continuous.

26. The method of claim 1 wherein the carbon composite material has a friction test showing an average slope greater than −0.09 NM/RPM between 20 and 60 RPM at 400 kPa.

27. The method of claim 26 further comprising incorporating the carbon composite material into a torque converter clutch.

28. The method of claim 27 further comprising incorporating the clutch in an automotive engine.

29. The method of claim 28 further comprising incorporating the engine into a motor vehicle.

30. The method of claim 1 further comprising incorporating the carbon composite material into a membrane electrode assembly for an electrochemical fuel cell.

31. The method of claim 30 further comprising incorporating the membrane electrode assembly into an electrochemical fuel cell.

32. The use of propane in continuous chemical vapor deposition of a carbon substrate.

33. The use of a densified substrate prepared by the method of claim 1 as a friction material.

34. A method for manufacturing a carbon composite friction material comprising:
providing a carbon substrate; and
depositing pyrolitic carbon on the carbon substrate by decomposing a propane gas at an elevated temperature sufficient to pyrolize the propane gas at a subatmospheric pressure to produce the friction material with a friction test having an average slope greater than −0.09 NM/RPM between 20 and 60 RPM at 400 kPa.

35. The method of claim 34 wherein the elevated temperature is below 2000° C.

36. The method of claim 34 wherein the elevated temperature is below −1800° C.

37. The method of claim 34 wherein the elevated temperature is below 1700° C.

38. The method of claim 34 wherein the elevated temperature is above 1200° C.

39. The method of claim 34 wherein the elevated temperature is above 1300° C.

40. The method of claim 34 wherein the elevated temperature is above 1500° C.

41. The method of claim 34 wherein the elevated temperature is about 1600° C.

42. The method of claim 34 wherein the propane gas is substantially pure propane.

43. The method of claim 34 wherein the propane gas is diluted with an inert carrier gas.

44. The method of claim 34 wherein the subatmospheric pressure is less than 100 mm Hg.

45. The method of claim 34 wherein the subatmospheric pressure is less than 50 mm Hg.

46. The method of claim 34 wherein the subatmospheric pressure is less than 10 mm Hg.

47. The method of claim 34 wherein the subatmospheric pressure is less than 5 mm Hg.

48. The method of claim 34 wherein the subatmospheric pressure is less than 3 mm Hg.

49. The method of claim 34 wherein the subatmospheric pressure is less than 1 mm Hg.

50. The method of claim 34 wherein the subatmospheric pressure is greater than 0.1 mm Hg.

51. The method of claim 34 wherein the subatmospheric pressure is from 0.1 to 1 mm of Hg.

52. The method of claim 34 wherein the carbon substrate is a carbon fabric.

53. The method of claim 52 wherein the carbon fabric is woven.

54. The method of claim 34 wherein the depositing step is for less than 10 hours.

55. The method of claim 34 wherein the depositing step is for less than 5 hours.

56. The method of claim 34 wherein the depositing step is for less than 3 hours.

57. The method of claim 34 wherein the depositing step is for less than 2 hours.

58. The method of claim 34 wherein the depositing step is for about 1 hour.

59. The method of claim 34 wherein the method is continuous.

60. The method of claim 34 further comprising incorporating the carbon composite friction material into a torque converter clutch.

61. The method of claim 60 further comprising incorporating the clutch in an automotive engine.

62. The method of claim 61 further comprising incorporating the engine into a motor vehicle.
